(19) United States
(12) Patent Application Publication
(10) Pub. No.: US 2026/0331895 A1
(43) Pub. Date: Oct. 22, 2026

(54) Electrical Network and Motor Vehicle

(71) Applicant: Volkswagen Aktiengesellschaft, Wolfsburg (DE)

(72) Inventors: Simon Tobias Hellmers, Wolfsburg (DE); Erik Hahn, Wolfsburg (DE); Henrik Schwarze, Wolfsburg (DE)

(73) Assignee: Volkswagen Aktiengesellschaft, Wolfsburg (DE)

(21) Appl. No.: 19/530,872

(22) Filed: Feb. 5, 2026

(30) Foreign Application Priority Data
Feb. 12, 2025 (DE) 10 2025 105 087.2

(51) Int. Cl. H02H 1/00; B60R 16/023; B60R 16/03; G01R 31/00; H02H 3/16

(52) U.S. Cl. CPC H02H 1/0061; B60R 16/0232; B60R 16/03; G01R 31/007; H02H 3/16

(57) ABSTRACT

The disclosure relates to an electrical network, comprising a master unit and at least one socket. The master unit and the at least one socket are connected to one another via power lines. The master unit a circuit breaker is arranged in at least one power line, wherein the master unit and the at least one socket are connected via at least one bus line. At least one processor is arranged in the master unit, the processor being configured to perform bus communication and to actuate the at least one circuit breaker. At least one fault current sensor is arranged in the at least one socket, the fault current sensor being connected to a manipulation circuit that is configured to generate a bus fault. The at least one processor is configured to open the at least one circuit breaker when a bus fault is detected.

### CROSS-REFERENCE TO RELATED APPLICATIONS

This application claims priority to German Patent Application DE 10 2025 105 087.2, filed on Feb. 12, 2025 with the German Patent and Trademark Office. The contents of the aforesaid Patent Application are incorporated herein for all purposes.

### BACKGROUND

This background section is provided for the purpose of generally describing the context of the disclosure. Work of the presently named inventor(s), to the extent the work is described in this background section, as well as aspects of the description that may not otherwise qualify as prior art at the time of filing, are neither expressly nor impliedly admitted as prior art against the present disclosure.

The disclosure relates to an electrical network and to a motor vehicle having such a network.

In regions with electrical equipment of Protection Class 0, the installation of residual-current circuit breakers (also known as RCDs, GFCIs or FI circuit breakers) is required by standards and by the concept of electrical safety when the “vehicle-to load” function is used. This results in additional installation space and costs, and additionally the testing of residual-current circuit breakers installed in electric sockets is labor-intensive.

DE 10 2006 048 073 A1 discloses an electrical circuit for operating a bus of a fieldbus system, comprising means for sensing a fault current. The means comprise first means for determining a first current of a first bus line, second means for determining a second current of a second bus line, and means for detecting a fault based on the first current and the second current. In this case, the means for detecting may be configured to detect a short circuit of a bus line to ground and/or a short circuit of a bus line to an external voltage.

### SUMMARY

A need exists to provide an electrical network with at least one socket and a residual-current circuit breaker, the electrical network being compact..

The need is addressed by the subject matter of the independent claim(s). Embodiments of the invention are described in the dependent claims, the following description, and the drawings.

### BRIEF DESCRIPTION OF THE DRAWINGS

FIG. 1 shows an electrical network according to a first embodiment and

FIG. 2 shows a socket according to a second embodiment.

### DESCRIPTION

The details of one or more embodiments are set forth in the accompanying drawing and the description below. Other features will be apparent from the description, drawing, and from the claims.

In the following description of embodiments of the invention, specific details are described in order to provide a thorough understanding of the invention. However, it will be apparent to one of ordinary skill in the art that the invention may be practiced without these specific details. In other instances, well-known features have not been described in detail to avoid unnecessarily complicating the instant description.

In some embodiments, an electrical network may comprise a master unit (also referred to as ‘master’ or ‘master device’) and at least one socket. The master unit and the at least one socket may be connected to one another via power supply lines. In the master unit, a circuit breaker may be arranged in at least one power line. Further, the at least one master unit and the at least one socket may be connected to one another via at least one bus line. At least one processor may be arranged in the master unit, the at least one processor being configured to perform bus communication and to actuate the at least one circuit breaker. At least one fault current sensor may be arranged in the at least one socket and is connected to a manipulation circuit that is configured to generate a bus fault. The at least one processor in the master unit may be configured to open the at least one circuit breaker in the event of a detected bus fault. In this way, the occurrence of a fault current can be transmitted very quickly to the master unit, which then centrally suppresses the power transmission. In this context, the transmission by generating the bus fault may be faster than a conventional bus message.

In some embodiments, the electrical network comprises a plurality of sockets, for example 2 to 8 sockets. However, additional sockets can be connected. An alternating voltage is for example transmitted via the power supply lines, wherein amplitude and frequency may vary depending on the country (e.g., 220 V at 50/60 Hz or 110 V at 50/60 Hz).

In some embodiments, two power supply lines are provided, wherein circuit breakers are arranged in each of the power supply lines in order to disconnect the power supply at all poles. For example, the fault current sensor may be configured as a toroidal coil, which is very robust and quickly generates a fault current signal that can be used directly to drive the manipulation circuit. The manipulation circuit may be, for example, a transistor circuit to manipulate a potential on the bus line (e.g., to pull it to ground).

In some embodiments, the master unit comprises an inverter, by means of which a DC voltage can be converted into a desired AC voltage.

In some embodiments, the processor in the master unit is configured, when a bus fault is detected, to switch off the inverter before the at least one circuit breaker is opened. As a result, the at least one circuit breaker is switched under no load.

In some embodiments, the at least one socket comprises a processor. This processor can perform various tasks and is used, for example, to communicate with the processor of the master unit via the at least one bus line.

In some embodiments, the at least one processor is connected to the at least one fault current sensor and is configured to store a fault event. It can thus be queried, for example, subsequently by the processor of the master unit which socket had the fault current and caused the shutoff of the power line.

In some embodiments, at least one diagnostic circuit is arranged in the at least one socket, the diagnostic circuit being connected to the processor of the socket, wherein the diagnostic circuit is configured to generate a fault current. In this way, the fault current sensor as well as the operability of the circuit breakers can be checked. Such a diagnostic mode is initiated, for example, by the processor of the master unit.

In some embodiments, the diagnostic circuit is connected to at least one power line, such that essentially a short circuit of the power line is simulated.

In some embodiments, the diagnostic circuit is connected to a DC voltage supply line and is configured to conduct a direct current through the fault current sensor for diagnostic purposes. The DC voltage supply line is, for example, a 12 V supply line (e.g., KL30), which is required in any case to supply the processor. A benefit is that the fault currents for diagnostic purposes are very small, and the diagnostic can also be performed when the power supply lines themselves are de-energized.

In some embodiments, the bus system of the bus line is a LIN bus system, which is very robust and simple.

In some embodiments, a motor vehicle is provided that comprises at least one electrical network according to one or more of the embodiments described herein.

Reference will now be made to the drawings in which the various elements of embodiments will be given numerical designations and in which further embodiments will be discussed.

Specific references to components, process steps, and other elements are not intended to be limiting. Further, it is understood that like parts bear the same or similar reference numerals when referring to alternate FIGS.

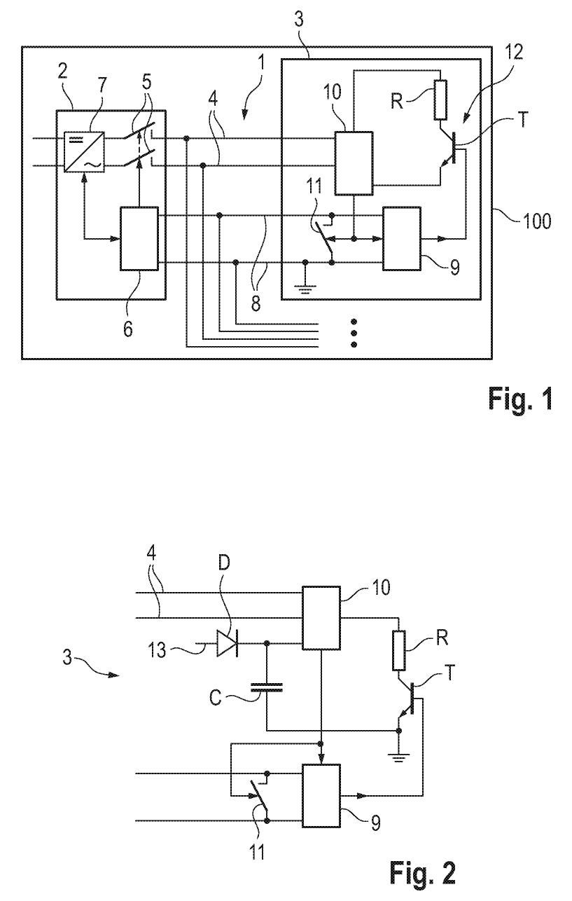

In FIG. 1, an electrical network 1 is shown in a motor vehicle 100. The electrical network 1 comprises a master unit 2 and at least one socket 3, wherein for example a plurality of sockets 3 are present, which is indicated by the dots. The master unit 2 and the socket 3 are connected to each other via power lines 4. In the master unit 2, circuit breakers 5, which are driven by a processor 6, are arranged in the power lines 4. Further, the master unit 2 comprises an inverter 7, which converts a DC voltage (e.g., from a high-voltage battery) into an AC voltage of a desired frequency and amplitude. Further, the master unit 2 and the socket 3 are connected to each other via two bus lines 8, wherein a processor 9 is also arranged in the socket 3. Corresponding transceivers for the bus communication are not shown for the sake of clarity. The socket 3 comprises a fault current sensor 10, which is configured, for example, as a toroidal coil. The fault current sensor 10 is connected, on the one hand, to the processor 9 and, on the other hand, to a manipulation circuit 11, wherein the manipulation circuit 11 is configured, for example, as a transistor which, in the conducting state, short-circuits the bus lines. Further, a diagnostic circuit 12, which comprises, for example, a resistor R and a transistor T, is arranged in the socket 3. The diagnostic circuit 12 is connected to the power lines 4 and is driven by the processor 9.

A principle of some embodiments of the teachings herein is that the circuit breakers 5 are centrally arranged in the master unit 2 and are centrally tripped in the event of fault current in a socket 3. By contrast, the fault current sensor 10 is arranged in a decentralized manner in the respective socket 3, i.e., each socket 3 has its own fault current sensor 10. Due to the distribution of the circuit breaker 5 and the fault current sensor 10, quick communication must now be ensured. This is done by the manipulation circuit 11, which disrupts the bus communication. The idea is that a disruption in the bus communication is detected by the processor 6 more quickly than the transmission of a regular bus message. The simplest case of disruption is to pull the upper bus line 8 permanently to 0 V, since, for example, most bus protocols specify how long 0 V is permitted to be present on both lines. If the clock signals on the bus lines have, for example, clock periods of 50 µs and at most eight zeros are permitted to be transmitted consecutively, then after 400 µs the processor 6 detects that a fault is present. The processor 6 then switches off the inverter 7 and opens the circuit breakers 5, which are configured, for example, as relays (contactors). Since the switch-off process of the inverter 7 is typically faster, the circuit breakers 5 are switched under no load.

If a plurality of sockets 3 are connected to the bus lines 5 and to the power lines 4, the master unit 2 does not know, in the event of a fault, which of the sockets 3 exhibited the fault current. However, since the fault current sensor 10 is connected to the processor 9 in its socket 3, the processor documents that it has been tripped. When the manipulation circuit 11 then opens again, the processor 6 in the master unit 2 can request the processors 9 in the sockets 3 to transmit their status (namely whether their fault current sensor 10 has been tripped). The master unit 2 can then transmit this information to a display unit or to another control device.

By means of the diagnostic circuit 12, the operability of the fault current sensor 10 and of the circuit breakers 5 can be checked. For this purpose, the inverter 7 transmits a diagnostic signal to the processor 6, or the processor 6 generates the diagnostic signal independently according to predetermined criteria (for example, after a predetermined time or a predetermined operating period). The processor 6 then transmits the diagnostic signal to a processor 9 of a socket 3. This processor then switches on the transistor T, so that a portion of the current is diverted through the transistor T, thereby generating an artificial fault current. The fault current sensor 10 then drives the manipulation circuit 11 in the fault-free state, which is detected by the processor 6. This can be repeated sequentially for all connected sockets 3.

Another embodiment of a socket 3 is shown in FIG. 2, wherein the only difference is the design of the diagnostic circuit 12. The diagnostic circuit 12 comprises a diode D, a capacitor C, a resistor R, and a transistor T, wherein the transistor T is driven by the processor 9. The diode D is connected to a DC voltage supply line 13, which carries, for example, 12 V DC (KL30) and provides the supply voltage for the processor 9. The DC voltage supply line 13 is conducted, via the diode D, through the fault current sensor 10, and from there via the resistor R and the transistor T to ground. Furthermore, the DC voltage supply line 13 is conducted to ground via the capacitor C downstream of the diode D and upstream of the fault current sensor 10. During normal operation, the transistor T turns off and no direct current flows through the fault current sensor 10. In the diagnostic mode, the transistor T is turned on and a direct current flows through the fault current sensor 10, and the fault current sensor then drives the manipulation circuit 11.

### LIST OF REFERENCE NUMERALS

1 Network
2 Master unit
3 Socket
4 Power line
5 Circuit breaker
6 Processor
7 Inverter
8 Bus line
9 Processor
10 Fault current sensor
11 Manipulation circuit
12 Diagnostic circuit
13 DC voltage supply line
100 Motor vehicle
C Capacitor
D Diode
R Resistor
T Transistor

The invention has been described in the preceding using various example embodiments. Other variations to the disclosed embodiments may be understood and effected by those skilled in the art in practicing the claimed invention, from a study of the drawings, the disclosure, and the appended claims. In the claims, the word "comprising" does not exclude other elements or steps, and the indefinite article "a" or "an" does not exclude a plurality. A single processor, device, or other unit may be arranged to fulfil the functions of several items recited in the claims. Likewise, multiple processors, devices, or other units may be arranged to fulfil the functions of several items recited in the claims.

The term "exemplary" used throughout the specification means "serving as an example, instance, or exemplification" and does not mean "preferred" or "having advantages" over other embodiments. The terms "in particular" and "particularly" used throughout the specification means "for example" or "for instance".

The mere fact that certain measures are recited in mutually different dependent claims or embodiments does not indicate that a combination of these measures cannot be used to advantage. Any reference signs in the claims should not be construed as limiting the scope.

What is claimed is:

1. An electrical network, comprising a master unit and at least one socket; wherein the master unit and the at least one socket are connected to one another via power lines; wherein in the master unit, a circuit breaker is arranged in at least one power line; wherein the master unit and the at least one socket are connected to one another via at least one bus line; wherein at least one processor is arranged in the master unit, the at least one processor being configured to perform bus communication and to actuate the at least one circuit breaker; wherein at least one fault current sensor is arranged in the at least one socket, the at least one fault current sensor being connected to a manipulation circuit that is configured to generate a bus condition/state; wherein the at least one processor is configured to open the at least one circuit breaker when the bus condition/state is detected.

2. The electrical network of claim 1, wherein the master unit comprises an inverter.

3. The electrical network of claim 2, wherein the at least one processor is configured, when the condition/state is detected, to first switch off the inverter before the at least one circuit breaker is opened.

4. The electrical network of claim 1, wherein the at least one socket comprises a processor.

5. The electrical network of claim 4, wherein the at least one processor is connected to the at least one fault current sensor and is configured to store a fault event.

6. The electrical network of claim 4, wherein at least one diagnostic circuit is arranged in the at least one socket, the diagnostic circuit being connected to the processor, wherein the diagnostic circuit is configured to generate a fault current.

7. The electrical network of claim 6, wherein the diagnostic circuit is connected to at least one power line.

8. The electrical network of claim 6, wherein the diagnostic circuit is connected to a DC voltage supply line and is configured to conduct a direct current through the fault current sensor for diagnostic purposes.

9. The electrical network of claim 1, wherein the bus system of the bus line is a LIN bus system.

10. A motor vehicle, wherein the motor vehicle comprises an electrical network, the electrical network comprising a master unit and at least one socket; wherein the master unit and the at least one socket are connected to one another via power lines; wherein in the master unit, a circuit breaker is arranged in at least one power line; wherein the master unit and the at least one socket are connected to one another via at least one bus line; wherein at least one processor is arranged in the master unit, the at least one processor being configured to perform bus communication and to actuate the at least one circuit breaker; wherein at least one fault current sensor is arranged in the at least one socket, the at least one fault current sensor being connected to a manipulation circuit that is configured to generate a bus condition/state; wherein the at least one processor is configured to open the at least one circuit breaker when the bus condition/state is detected.

11. The electrical network of claim 5, wherein at least one diagnostic circuit is arranged in the at least one socket, the diagnostic circuit being connected to the processor, wherein the diagnostic circuit is configured to generate a fault current.

12. The motor vehicle of claim 10, wherein the master unit comprises an inverter.

13. The motor vehicle of claim 12, wherein the at least one processor is configured, when the bus condition/state fault is detected, to first switch off the inverter before the at least one circuit breaker is opened.

14. The motor vehicle of claim 10, wherein the at least one socket comprises a processor.

15. The motor vehicle of claim 14, wherein the at least one processor is connected to the at least one fault current sensor and is configured to store a fault event.

16. The motor vehicle of claim 14, wherein at least one diagnostic circuit is arranged in the at least one socket, the diagnostic circuit being connected to the processor, wherein the diagnostic circuit is configured to generate a fault current.

17. The motor vehicle of claim 15, wherein at least one diagnostic circuit is arranged in the at least one socket, the diagnostic circuit being connected to the processor, wherein the diagnostic circuit is configured to generate a fault current.

18. The motor vehicle of claim 16, wherein the diagnostic circuit is connected to at least one power line.

19. The motor vehicle of claim 16, wherein the diagnostic circuit is connected to a DC voltage supply line and is configured to conduct a direct current through the fault current sensor for diagnostic purposes.

20. The motor vehicle of claim 10, wherein the bus system of the bus line is a LIN bus system.
